(19) United States
(12) Patent Application Publication
(10) Pub. No.: US 2015/0255171 A1
(43) Pub. Date: Sep. 10, 2015

(54) DISPLAY DEVICE

(71) Applicant: Sharp Kabushiki Kaisha, Osaka-shi, Osaka (JP)

(72) Inventors: Shuji Nishi, Osaka-shi (JP); Yuhichiroh Murakami, Osaka-shi (JP); Yasushi Sasaki, Osaka-shi (JP)

(21) Appl. No.: 14/431,827

(22) PCT Filed: Sep. 27, 2013
(86) PCT No.: PCT/JP2013/076213

§ 371 Date: Mar. 27, 2015

(30) Foreign Application Priority Data
Oct. 5, 2012 (JP) 2012-222906

(51) Int. Cl. G11C 19/28; G02F 1/1345; G09G 3/36

(52) U.S. Cl. CPC G11C 19/28; G09G 3/3677; G02F 1/13454; G09G 2310/0286; G09G 2300/0426

(57) ABSTRACT

An objective of the present invention is to provide a display device capable of suppressing consumption of the current flowing through gate clock signal bus lines by reducing the loads on the gate clock signal bus lines.

In a shift register, which writes the voltages of a plurality of gate clock signals (CK1 to CK3) to gate bus lines (GL) via buffer circuits (BF), a plurality of gate clock signal bus lines (51a to 54a) are formed in an area between a display portion (600) and the buffer circuits (BF), independently of a clear signal bus line and other lines, so as to be adjacent to the buffer circuits (BF). This results in no area in which clear signal branch lines (61b) cross the gate clock signal bus lines (51a to 54a) and wiring lines in bistable circuits SR. Thus, it is possible to eliminate interlayer capacitance due to the crossings of the lines and fringe capacitance between the lines.

### TECHNICAL FIELD

The present invention relates to active-matrix display devices, more specifically to the layout of the wiring near a scanning signal line driver circuit.

### BACKGROUND ART

Conventionally, in liquid crystal display devices employing a-SiTFT liquid crystal panels (i.e., liquid crystal panels with thin-film transistors whose semiconductor layers are made with amorphous silicon), gate drivers for driving gate bus lines are mounted around substrates included in the panels as IC (Integrated Circuit) chips because the mobility of amorphous silicon is relatively low. However, in recent years, to render liquid crystal display devices more compact and less expensive, gate drivers are formed directly on substrates. Such a gate driver is referred to as, for example, a “monolithic gate driver”.

The gate driver of such a conventional liquid crystal display device includes a shift register consisting of a plurality of stages to sequentially drive a plurality of gate bus lines formed in a display portion, and wiring lines for transmitting gate clock signals to activate the shift register and wiring lines for transmitting control signals are formed together in the same area near the shift register.

FIG. 19 is a diagram illustrating a gate driver in a conventional liquid crystal display device and an example of the wiring in the proximity. Each stage of a shift register shown in FIG. 19 consists of a bistable circuit SR and a buffer circuit BF connected to the bistable circuit SR, and the shift register provides clock signals, which are supplied through wiring lines 51a to 53a (gate clock signal bus lines) for transmitting gate clock signals, to corresponding gate bus lines in a display portion 600 as scanning signals G in accordance with status signals (buffer control signals) outputted by the bistable circuits SR. In such a gate driver, the stages of the shift register, each consisting of the bistable circuit SR and the buffer circuit BF connected to the bistable circuit SR, are arranged along the display portion 600, and the wiring lines 51a to 53a (gate clock signal bus lines) for transmitting gate clock signals are disposed in an area between the shift register and the edge of the liquid crystal panel, along with a wiring line 61a (clear signal bus line) for transmitting control signals such as a clear signal CLR.

In relevance to the present invention, Japanese

Laid-Open Patent Publication No. 2006-85118 is known. This prior patent document discloses a liquid crystal display device in which gate clock signal lines for transmitting gate clock signals are formed on the opposite side from a display portion with respect to a shift register.

### PRIOR ART DOCUMENT

### Patent Document

Patent Document 1: Japanese Laid-Open Patent Publication No. 2006-85118

### SUMMARY OF THE INVENTION

### Problems to be Solved by the Invention

However, in the case of the conventional wiring shown in FIG. 19, for example, there is an area as denoted by the reference numeral “70” in which a wiring line 61b (clear signal branch line) for connecting a clear signal bus line 61a and the bistable circuit SR crosses the gate clock signal bus lines 51a to 51c. This crossing area increases interlayer capacitance between the gate clock signal bus lines 51a to 53a and the clear signal branch line 61b. Moreover, the gate clock signal bus lines 51a to 53a are formed away from the buffer circuit BF, resulting in significant distances between the gate clock signal bus lines 51a to 53a and the buffer circuit BF and thereby increased wiring resistance of the gate clock signal bus lines 51a to 53a. These increases in interlayer capacitance and wiring resistance result in a problem with increased loads on the gate clock signal bus lines 51a to 53a and increased current consumption. This problem occurs also in the liquid crystal display device described in Japanese Laid-Open Patent Publication No. 2006-85118.

Therefore, an objective of the present invention is to provide a display device capable of suppressing consumption of the current flowing through gate clock signal bus lines by reducing loads on gate clock signal bus lines.

### Means for Solving the Problems

According to a first aspect of the present invention, there is provided a liquid crystal display device including:
a substrate;
pixel circuits formed in a display area on the substrate in which to display an image;
a plurality of scanning signal lines formed in the display area, each constituting a part of the pixel circuit;
a shift register formed on the substrate and having a plurality of bistable circuits and a plurality of buffer circuits, the bistable circuits having first and second states and being provided in one-to-one correspondence with the scanning signal lines, the buffer circuits being connected in series to the respective bistable circuits so as to, when the bistable circuits are sequentially brought into the first. state, output clock signals provided by a plurality of clock signal bus lines for transmitting the respective clock signals, to the scanning signal lines being driven sequentially by the stable circuits being sequentially brought into the first state; and
control signal bus lines formed in an area opposite to the display area with respect to a shift register area in which the shift register is formed, the control signal bus lines transmitting control signals for controlling the operation of the bistable circuits and being connected to the bistable circuits by control signal branch lines, wherein,
the buffer circuits are formed in a line within the shift register area so as to be opposed to the display area, and
the clock signal bus lines are formed in an area between the shift register area and the display area so as to be adjacent to the buffer circuits.

According to a second aspect of the present invention, in the first aspect of the present invention, wherein,
the substrate has a layered structure including a first metallic film and a second metallic film, the first metallic film forming a wiring pattern including source electrodes of thin-film transistors provided in the bistable circuits, the second metallic film forming a wiring pattern including gate electrodes of the thin-film transistors, and
the clock signal bus lines and the clock signal branch lines are respectively formed with the first metallic film and the second metallic film.

According to a third aspect of the present invention, in the second aspect of the present invention, wherein,
each of the bistable circuits includes a set signal input terminal for receiving a set signal and a reset signal input terminal for receiving a reset signal,
each of the buffer circuits has an output line connected by a set signal line to a set signal input terminal of the bistable circuit in the next stage and also connected by a reset signal line to a reset signal input terminal of the bistable circuit in the previous stage, and
the set signal line and the reset signal line are formed with the same metallic film as the output line.

According to a fourth aspect of the present invention, in the second aspect of the present invention, wherein,
each of the buffer circuits includes a single thin-film transistor,
the thin-film transistor has an input electrode connected to one of the clock signal bus lines, an output electrode connected to one of the scanning signal lines, and a control electrode connected to an output terminal of one of the bistable circuits, and
the input electrode and the output electrode are formed with the same metallic film as the clock signal bus lines.

According to a fifth aspect of the present invention, in the fourth aspect of the present invention, wherein each of the clock signal branch lines is formed extending to a position at which to be connected to the clock signal bus line that is connected to the input electrode.

According to a sixth aspect of the present invention, in the fourth aspect of the present invention, wherein the thin-film transistor has a semiconductor layer made with InGaZnOx mainly composed of indium (In), gallium (Ga), zinc (Zn), and oxygen (O).

According to a seventh aspect of the present invention, in the second aspect of the present invention, wherein the buffer circuits have first and second input terminals and output terminals and include CMOS logic gate circuits for outputting scanning signals to the scanning signal lines when the respective bistable circuits are in the first state.

According to an eighth aspect of the present invention, in the second aspect of the present invention, wherein the control signal bus line is formed with the first metallic film and the control signal branch line is formed with the second metallic film.

### Effect of the Invention

In the first aspect of the present invention, in the shift register, which writes clock signal voltages to the scanning signal lines via the buffer circuits, the clock signal bus lines, unlike the control signal bus lines and so on, are formed adjacent to the buffer circuits in an area between the display portion and the buffer circuits. This results in no area in which the control signal branch lines cross the clock signal bus lines and the wiring lines in the bistable circuits. Therefore, interlayer capacitance due to the crossings of the lines and fringe capacitance between the wiring lines can be eliminated, leaving only interlayer capacitance between the clock signal bus lines and the clock signal branch lines and fringe capacitance between adjacent gate clock signal bus lines. In addition, the clock signal bus lines are disposed near the buffer circuits, so that the distance from each clock signal bus line to the buffer circuit is short, resulting in reduced wiring resistance. Thus, the loads on the gate clock signal bus lines can be reduced, whereby consumption of the current flowing through the clock signal bus lines can be reduced.

In the second aspect of the present invention, the clock signal bus lines are made with the first metallic film, and the clock signal branch lines are made with the second metallic film. Thus, it is possible to readily apply a layout so as to reduce interlayer capacitance due to the clock signal bus lines crossing the clock signal branch lines.

In the third aspect of the present invention, the set signal lines for providing set signals to the bistable circuits and the reset signal lines for providing reset signals to the bistable circuits are formed of the same metallic film as the output lines of the buffer circuits. Accordingly, it is possible to readily apply a layout such that the output signal of each unit circuit is provided to the unit circuit in the next stage as the set signal or to the unit circuit in the previous stage as the reset signal.

In the fourth aspect of the present invention, the buffer circuit is formed by a single thin-film transistor, and the input electrode and the output electrode of the thin-film transistor is formed with the same metallic film as the clock signal bus line. Accordingly, it is possible to readily achieve a layout such that the input electrodes are connected to the clock signal bus lines, and the output electrodes are connected to the scanning signal lines.

In the fifth aspect of the present invention, the clock signal branch line is formed extending to a position at which to be connected to the clock signal bus line that is connected to the input electrode. Thus, it is possible to minimize the interlayer capacitance formed by the clock signal bus lines and the clock signal branch lines, resulting in reduced loads on the clock signal bus lines and suppressed current consumption.

In the sixth aspect of the present invention, the thin-film transistors, which serve as the buffer circuits and have semiconductor layers made with indium gallium zinc oxide, are used as drive elements of the scanning signal line driver circuit, resulting in a reduced frame area and an increase in display resolution.

In the seventh aspect of the present invention, even when the levels of clock signals are low, the clock signals can be amplified by the buffer circuits, and therefore, it is possible to output scanning signals at sufficient levels to the scanning signal lines. Accordingly, it is possible to further reduce current consumption by the clock signal bus lines.

In the eighth aspect of the present invention, even when the control signal branch lines are formed with the second metallic film, the clock signal bus lines are formed in the area between the display portion and the buffer circuits, and therefore, no interlayer capacitance is formed by the control signal branch lines crossing the clock signal bus lines.

### BRIEF DESCRIPTION OF THE DRAWINGS

FIG. 1 is a block diagram illustrating the overall configuration of an active-matrix liquid crystal display device according to a first embodiment of the present invention.

FIG. 2 is a block diagram describing the configuration of a gate driver in the first embodiment.

FIG. 3 is a block diagram illustrating the configuration of a shift register in the gate driver in the first embodiment.

FIG. 4 provides signal waveform charts describing the operation of the gate driver in the first embodiment.

FIG. 5 is a circuit diagram illustrating the configuration of a stage (unit circuit) in the shift register in the first embodiment.

FIG. 6 provides signal waveform charts describing the operation of the shift register in the first embodiment.

FIG. 7 is a diagram illustrating the layout of a wiring pattern near the gate driver in the first embodiment.

FIG. 8 is a layout diagram of the wiring near the gate driver in the first embodiment.

FIG. 9 is a cross-sectional view including a source electrode of a thin-film transistor, which serves as a buffer circuit, and its vicinity in the first embodiment.

FIG. 10 is a cross-sectional view including a drain electrode of the thin-film transistor, which serves as the buffer circuit, and its vicinity in the first embodiment.

FIG. 11 is a block diagram illustrating the configuration of a shift register in a gate driver in a liquid crystal display device according to a second embodiment of the present invention.

FIG. 12 provides signal waveform charts describing the operation of the gate driver in the second embodiment.

FIG. 13 provides signal waveform charts describing the operation of the gate driver in the second embodiment.

FIG. 14 is a circuit diagram illustrating an exemplary configuration of a stage (unit circuit) in the shift register in the second embodiment.

FIG. 15 provides signal waveform charts describing the operation of the shift register in the second embodiment.

FIG. 16 is a diagram illustrating the layout of a wiring pattern near the gate driver in the second embodiment.

FIG. 17 is a block diagram illustrating the configuration of a buffer circuit in a shift register of a liquid crystal display device according to a third embodiment of the present invention.

FIG. 18 is a layout diagram of the wiring near a gate driver in the third embodiment.

FIG. 19 is a diagram illustrating a gate driver in a conventional liquid crystal display device and an example of the wiring in the proximity.

### MODES FOR CARRYING OUT THE INVENTION

Hereinafter, embodiments of the present invention will be described with reference to the accompanying drawings.

### 1. First Embodiment

### 1.1 Overall Configuration

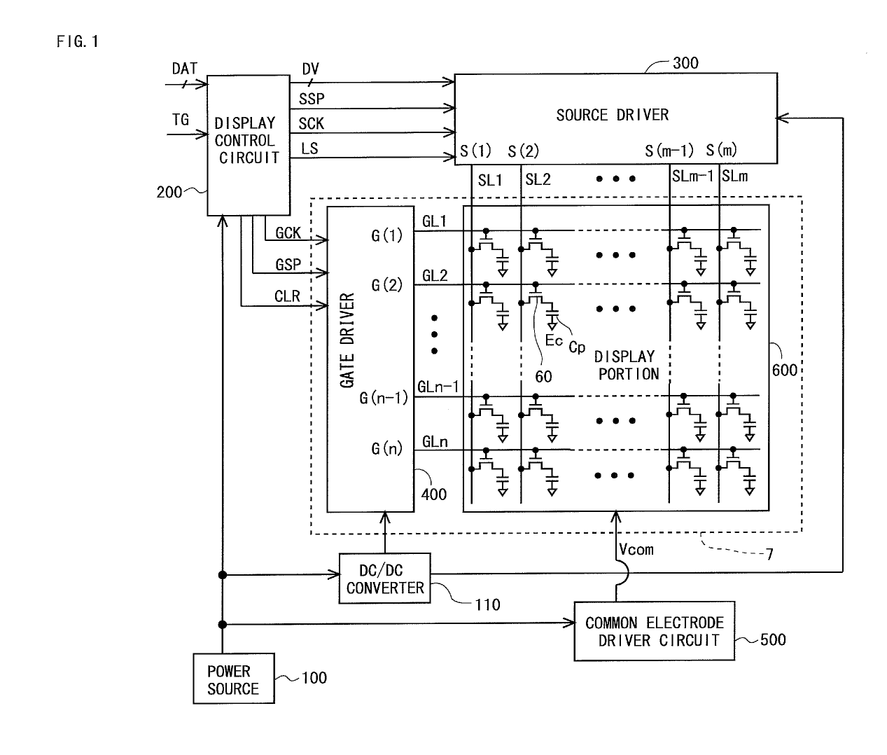

FIG. 1 is a block diagram illustrating the overall configuration of an active-matrix liquid crystal display device according to a first embodiment of the present invention. This liquid crystal display device includes a power source 100, a DC/DC converter 110, a display control circuit 200, a source driver (video signal line driver circuit) 300, a gate driver (scanning signal line driver circuit) 400, a common electrode driver circuit 500, and a display portion 600, as shown in FIG. 1.

The display portion 600 has a plurality (m) of source bus lines (video signal lines) SL1 to SLm, a plurality (n) of gate bus lines (scanning signal lines) GL1 to GLn, and a plurality (n×m) of pixel forming portions formed corresponding to the intersections of the source bus lines SL1 to SLm and the gate bus lines GL1 to GLn.

The pixel forming portions are arranged in a matrix to constitute a pixel array. Each pixel forming portion includes a thin-film transistor (TFT) 60, which functions as a switching element and has a gate terminal connected to a gate bus line passing through a corresponding intersection, as well as a source terminal connected to a source bus line passing through the intersection, a pixel electrode connected to a drain terminal of the thin-film transistor 60, a common electrode Ec commonly provided for the pixel forming portions, and a liquid crystal layer commonly provided for the pixel forming portions between the pixel electrode and the common electrode Ec. The pixel electrode and the common electrode Ec form liquid crystal capacitance, which constitutes pixel capacitance Cp. Note that auxiliary capacitance is typically provided parallel to the liquid crystal capacitance, but the auxiliary capacitance is not directly relevant to the present invention, and therefore, any description and illustration thereof will be omitted.

The power source 100 supplies a predetermined power source voltage to the DC/DC converter 110, the display control circuit 200, and the common electrode driver circuit 500. The DC/DC converter 110 generates a predetermined direct-current voltage from the power source voltage in order to activate the source driver 300 and the gate driver 400, and supplies the generated voltage to the source driver 300 and the gate driver 400. The common electrode driver circuit 500 provides a predetermined common potential Vcom to the common electrode Ec.

The display control circuit 200 receives externally transmitted signals, including an image signal DAT as well as a timing signal group TG, which includes a horizontal synchronization signal, a vertical synchronization signal, etc., and outputs a digital video signal DV as well as signals for controlling image display on the display portion 600, including a source start pulse signal SSP, a source clock signal SCK, a latch strobe signal LS, a gate start pulse signal GSP, and a gate clock signal GCK. Note that in the present embodiment, the gate clock signal GCK consists of three clock signals: CK1 (referred to below as a “first gate clock signal CK1”), CK2 (referred to below as a “second gate clock signal CK2”), and CK3 (referred to below as a “third gate clock signal CK3”).

The source driver 300 receives the digital video signal DV, the source start pulse signal SSP, the source clock signal SCK, and the latch strobe signal LS outputted by the display control circuit 200, and applies drive video signals S(1) to S(m) to the source bus lines SL1 to SLm, respectively.

In accordance with the gate start pulse signal GSP, the gate clock signal GCK, and a clear signal CLR outputted by the display control circuit 200, the gate driver 400 repeats applying active scanning signals G(1) to G(n) sequentially to the gate bus lines GL1 to GLn in cycles of one vertical scanning period. Note that the gate driver 400 will be described in detail later.

The gate driver 400 and the source driver 300, along with the switching elements in the pixel forming portions, are formed on the same array substrate 7 as the display portion 600 using thin-film transistors whose semiconductor layers are made with amorphous silicon, polycrystalline silicon, microcrystalline silicon, or an oxide semiconductor. The mobility of the oxide semiconductor is higher than the mobility of silicon-based materials such as amorphous silicon, and therefore, by using thin-film transistors whose semiconductor layers are made with the oxide semiconductor as drive elements, it is rendered possible to realize a reduced frame area and an increase in display resolution. An example of the oxide semiconductor used is InGaZnOx (indium gallium zinc oxide) mainly composed of indium (In), gallium (Ga), zinc (Zn), and oxygen (O).

As described above, the drive video signals S(1) to S(m) are applied to the source bus lines SL1 to SLm, and the scanning signals G(1) to G(n) are applied to the gate bus lines GL1 to GLn, so that the display portion 600 displays an image based on the externally transmitted image signal DAT.

### 1.2 Configurations of the Gate Driver and the Shift Register

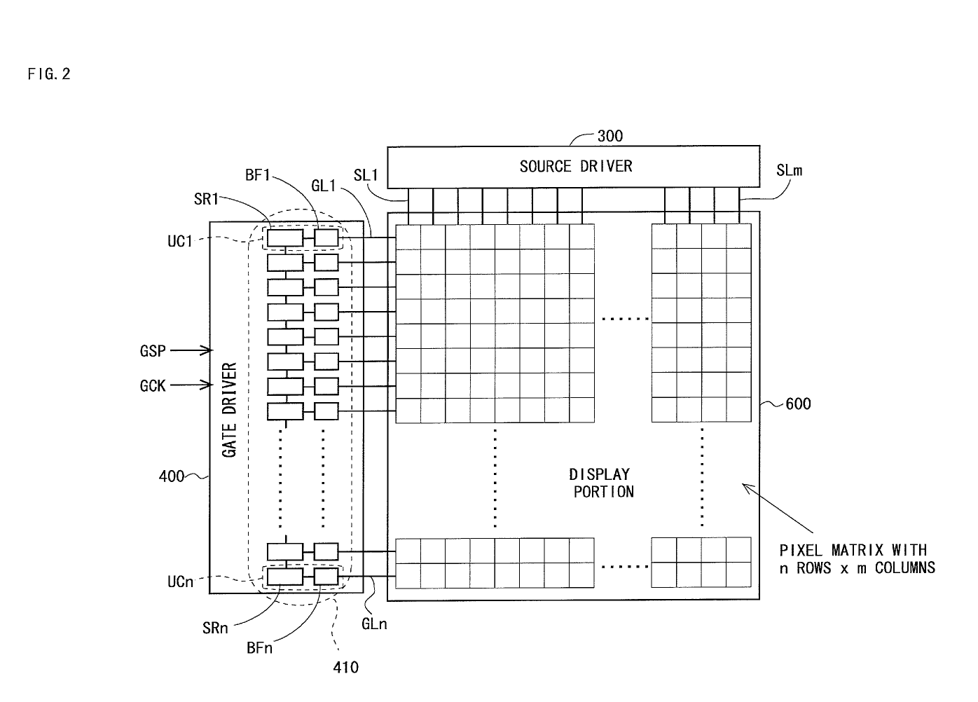

Next, the configuration of the gate driver 400 in the present embodiment will be described. FIG. 2 is a block diagram illustrating the configuration of the gate driver in the present embodiment. The gate driver 400 includes a shift register 410 consisting of a plurality of stages (unit circuits), as shown in FIG. 2. The display portion 600 has a pixel matrix formed of n rows×m columns, and the stages (unit circuits) of the shift register 410 are provided in one-to-one correspondence with the rows of the pixel matrix. More specifically, the shift register 410 includes n unit circuits UC1 to UCn. Each unit circuit UC includes a bistable circuit SR, and a buffer circuit BF connected to the bistable circuit SR, as will be described later. The bistable circuit SR is a circuit for outputting a status signal (buffer control signal) to the buffer circuit BF, and the buffer circuit BF is a circuit for driving the gate bus line and the pixel forming portion. The n bistable circuits SR1 to SRn are connected in series to one another. The n buffer circuits BF1 to BFn respectively connect the bistable circuits SR1 to SRn to the gate bus lines GL1 to GLn.

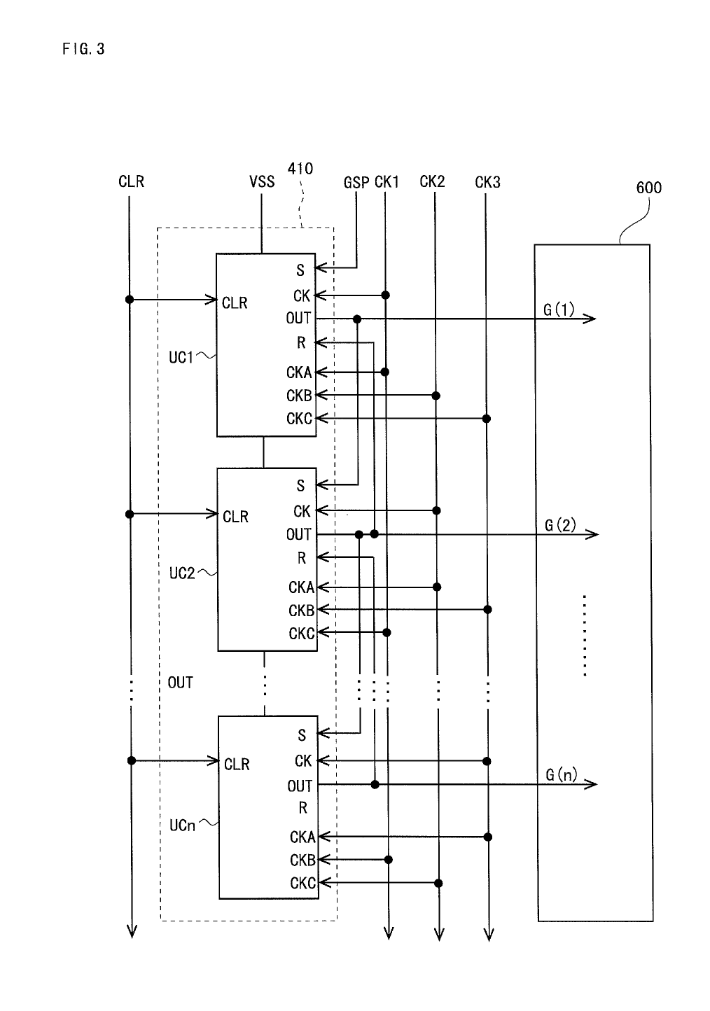

FIG. 3 is a block diagram illustrating the configuration of the shift register 410 in the gate driver 400. As described above, the shift register 410 includes the n unit circuits UC1 to UCn. In the present embodiment, the shift register 410 is provided with the gate start pulse signal GSP, the clear signal CLR, and the three-phase gate clock signal. The three-phase gate clock signal consists of the first gate clock signal CK1, the second gate clock signal CK2, and the third gate clock signal CK3. Each unit circuit is provided with an input terminal for receiving a clock signal CKA (referred to below as a “first clock”), a clock signal CKB (referred to below as a “second clock”), and a clock signal CKC (referred to below as a “third clock”), an input terminal for receiving a set signal S, an input terminal for receiving a reset signal R, an input terminal for receiving a clear signal CLR, and an output terminal for outputting gate clock signals CK1 to CK3 as output signals OUT. The gate clock signals CK1 to CK3 alternate between a high-level power source potential VDD and a low-level power source potential VSS in predetermined cycles.

In the present embodiment, the gate clock signals CK1 to CK3 are provided to the shift register 410 as described below. The first gate clock signal CK1, the second gate clock signal CK2, and the third gate clock signal CK3 are provided to the first-stage unit circuit UC1 as a first clock CKA, a second clock CKB, and a third clock CKC, respectively. The second gate clock signal CK2, the third gate clock signal CK3, and the first gate clock signal CK1 are provided to the second-stage unit circuit UC2 as a first clock CKA, a second clock CKB, and a third clock CKC, respectively. The third gate clock signal CK3, the first gate clock signal CK1, and the second gate clock signal CK2 are provided to the third-stage unit circuit UC3 as a first clock CKA, a second clock CKB, and a third clock CKC, respectively. Similar arrangements to the above arrangements for the first- to third-stage unit circuits UC1 to UC3 are repeated every three stages.

Furthermore, each stage (i.e., each unit circuit) is provided with a set signal S, which is an output signal OUT from the previous stage, as well as a reset signal R, which is an output signal OUT from the next stage. That is, the output signal OUT from each unit circuit is provided not only to the gate bus line as a scanning signal but also to the next stage as a set signal S and to the previous stage as a reset signal R. Note that the set signal S that is provided to the first-stage unit circuit UC1 is the gate start pulse signal GSP.

Note that the gate driver 400 in the present embodiment is configured such that the order of scanning the gate bus lines GL1 to GLn can be changed. However, the changing of the scanning order is not directly relevant to the present invention, therefore, forward scanning will be described in the following, and any description of backward scanning will be omitted.

### 1.3 Operation of the Shift Register

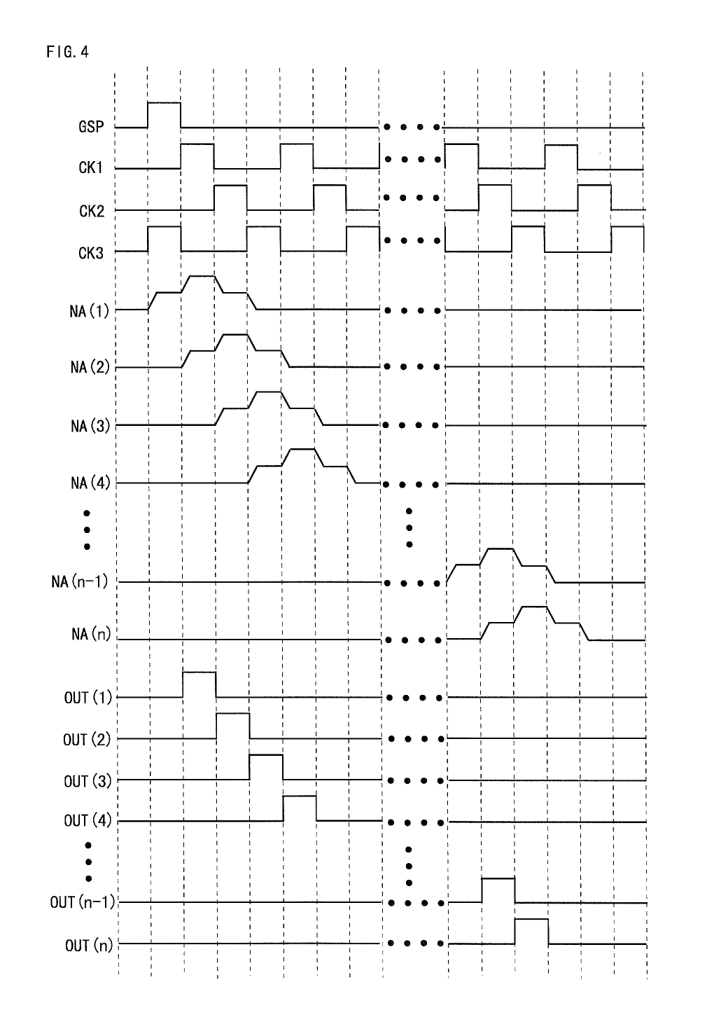

FIG. 4 provides signal waveform charts describing the operation of the gate driver 400. In the gate driver 400, when forward scanning is performed, the gate clock signals CK1 to CK3 with the waveforms as shown in FIG. 4 are provided to the shift register 410. The second gate clock signal CK2 is 120 degrees behind in phase relative to the first gate clock signal CK1, and the third gate clock signal CK3 is 120 degrees ahead in phase relative to the first gate clock signal CK1. Moreover, the gate start pulse signal GSP rises simultaneously with the third gate clock signal CK3. As a result, the three gate clock signals are generated in the order, from the rise of the gate start pulse signal GSP: the third gate clock signal CK3; the first gate clock signal CK1; and the second gate clock signal CK2.

When a pulse of the gate start pulse signal GSP is provided to the first-stage unit circuit UC1 of the shift register 410 as a set signal S, pulses included in the gate start pulse signal GSP are sequentially transferred to the unit circuits UC1 to UCn in the first through the n'th stages in accordance with the gate clock signals CK1 to CK3. As a result of this pulse transfer, the output signals OUT(1) to OUT(n) from the unit circuits UC1 to UCn of the shift register 410 are sequentially set to high level. The output signals OUT(1) to OUT(n) from the unit circuits UC1 to UCn are provided to the gate bus lines GL1 to GLn, respectively, as scanning signals G(1) to G(n). Consequently, the scanning signals G(1) to G(n), which are sequentially set at high level for one horizontal scanning period as shown in FIG. 4, are provided to the gate bus lines in the display portion 600.

### 1.4 Configuration and Operation of the Unit Circuit

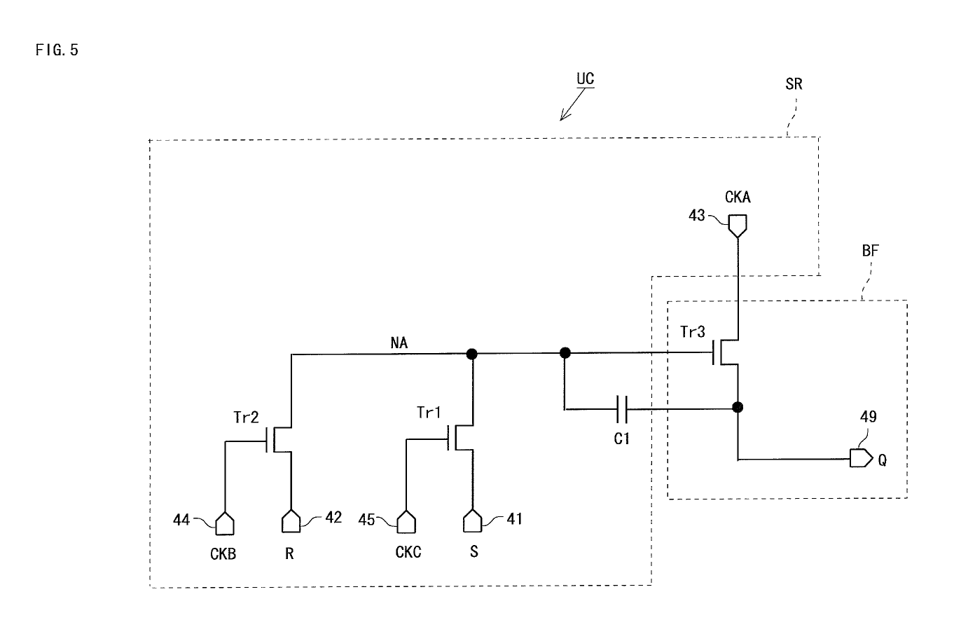

FIG. 5 is a circuit diagram illustrating the configuration of the unit circuit UC in the shift register 410. The unit circuit UC includes three thin-film transistors Tr1 to Tr3 and a capacitor C1, as shown in FIG. 5. Moreover, the unit circuit UC has five input terminals 41 to 45 and an output terminal 49. The output terminal 49 is connected to the gate bus line. Note that the input terminal at which to receive the set signal S is denoted by the reference numeral “41”, and the input terminal at which to receive the reset signal R is denoted by the reference numeral “42”. Further, the input terminal at which to receive the first clock CKA is denoted by the reference numeral “43”, the input terminal at which to receive the second clock CKB is denoted by the reference numeral “44”, and the input terminal at which to receive the third clock CKC is denoted by the reference numeral “45”. Note that the thin-film transistor Tr3 and the output terminal 49 constitute the buffer circuit BF, and the thin-film transistors Tr1 and Tr2, the capacitor C1, and the input terminals 41 to 45 constitute the bistable circuit SR.

Next, the connection relationship between the components in the unit circuit UC will be described. A drain terminal of the thin-film transistor Tr1, a drain terminal of the thin-film transistor Tr2, and a gate terminal of the thin-film transistor Tr3 are connected to one another. Note that the line that connects them will be referred to as the “node” and is denoted by NA in the figure.

The thin-film transistor Tr1 is connected at a gate terminal to the input terminal 45 and at a source terminal to the input terminal 41. The thin-film transistor Tr2 is connected at a gate terminal to the input terminal 44 and at a source terminal to the input terminal 42. The thin-film transistor Tr3 is connected at the gate terminal to the node NA, at a drain terminal to the input terminal 43, and at a source terminal to the output terminal 49. The capacitor C1 is connected between the gate terminal and the source terminal of the thin-film transistor Tr3.

Next, the function of each component will be described. The thin-film transistor Tr1 provides the potential of the set signal S to the node NA when the third clock CKC is at high level. The thin-film transistor Tr2 provides the potential of the reset signal R to the node NA when the second clock CKB is at high level. The thin-film transistor Tr3 provides the potential of the first clock CKA to the output terminal 49 when the potential of the node NA is at high level. The capacitor C1 functions as compensation capacitance to maintain the potential of the node NA at high level for a period in which the gate bus line connected to the unit circuit is in a selected state (i.e., in an active state).

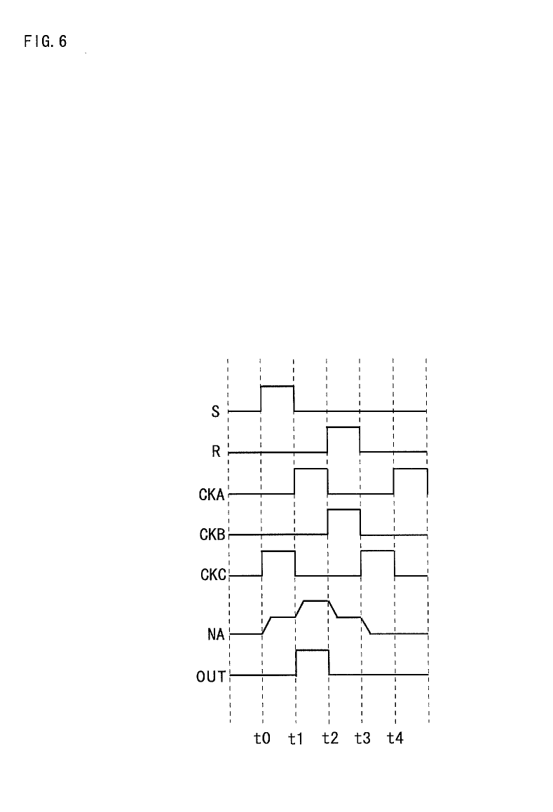

Next, the operation of the unit circuit UC will be described. FIG. 6 provides signal waveform charts describing the operation of the shift register 410. The potential of the node NA and the potential of the output signal OUT (i.e., the potential of the output terminal 49) are initially at low level. At time t0, the set signal S changes from low level to high level, and the third clock CKC changes from low level to high level, so that the thin-film transistor Tr1 is brought into on-state. As a result, the potential of the node NA changes from low level to high level, so that the node NA is brought into a precharged state, and the thin-film transistor Tr3 is brought into on-state. At this time, the first clock CKA is at low level, and therefore, the output signal OUT is maintained at low level.

At time t1, the first clock CKA changes from low level to high level. At this time, the thin-film transistor Tr3 is in on-state, and therefore, the potential of the input terminal 43 rises, and the potential of the output terminal 49 rises as well. The potential of the node NA rises by virtue of bootstrap effect due to the capacitor C1 as the potential of the output terminal 49 rises. Consequently, a high voltage is applied to the gate terminal of the thin-film transistor Tr3, and the potential of the output terminal 49 rises without falling short of the potential of the first clock CKA at high level by the value of a threshold voltage. In this manner, the gate bus line connected to the output terminal 49 of the unit circuit is brought into a selected state.

At time t2, the first clock CKA changes from high level to low level. As a result, the potential of the input terminal 43 decreases, and the potential of the output terminal 49 decreases to low level. Moreover, the potential of the node NA decreases because of the capacitor C1. In addition, both the reset signal R and the second clock CKB change from low level to high level. As a result, the thin-film transistor Tr2 is brought into on-state, and the node NA is brought into a precharged state.

At time t3, the second clock CKB changes from high level to low level, and the third clock CKC changes from low level to high level. As a result, the thin-film transistor Tr2 is brought into off-state, and the thin-film transistor Tr1 is brought into on-state. Further, the set signal S remains at low level. Accordingly, the potential of the node NA is set to low level.

Next, the overall operation of the shift register 410 will be described. Initially, when the gate start pulse signal GSP and the third gate clock signal CK3 rise, the potential of the node NA(1) in the first-stage unit circuit UC1 shown in FIG. 3 rises significantly by virtue of bootstrap effect. As a result, the potential of the output signal OUT(1) from the first-stage unit circuit UC1 rises without falling short of the high-level power source potential VDD by the value of the threshold voltage. At this time, the node NA(2) of the second-stage unit circuit UC2 is precharged.

Subsequently, when the second gate clock signal CK2 rises, the potential of the output signal OUT(2) from the second-stage unit circuit UC2 rises without falling short of the high-level power source potential VDD by the value of the threshold voltage. At this time, the node NA(3) of the third-stage unit circuit UC3 is precharged. In addition, the first gate clock signal CK1 falls, so that the potential of the node NA(1) in the first-stage unit circuit UC1 decreases.

Thereafter, when the third gate clock signal CK3 rises, the potential of the output signal OUT(3) from the third-stage unit circuit UC3 rises without falling short of the high-level power source potential VDD by the value of the threshold voltage. At this time, the node NA(4) of the fourth-stage unit circuit UC4 is precharged. In addition, the second gate clock signal CK2 falls, so that the potential of the node NA(2) in the second-stage unit circuit UC2 decreases.

The above operations will be repeated so that significant increases in potential due to bootstrap effect occur sequentially in the nodes NA(1) to NA(n) of the first-to n'th-stage unit circuits UC1 to UCn, and the output signals OUT(1) to OUT(n) respectively provided by the unit circuits UC1 to UCn are sequentially set at high level for a predetermined period of time.

### 1.5 Layout of the Wiring Near the Gate Driver

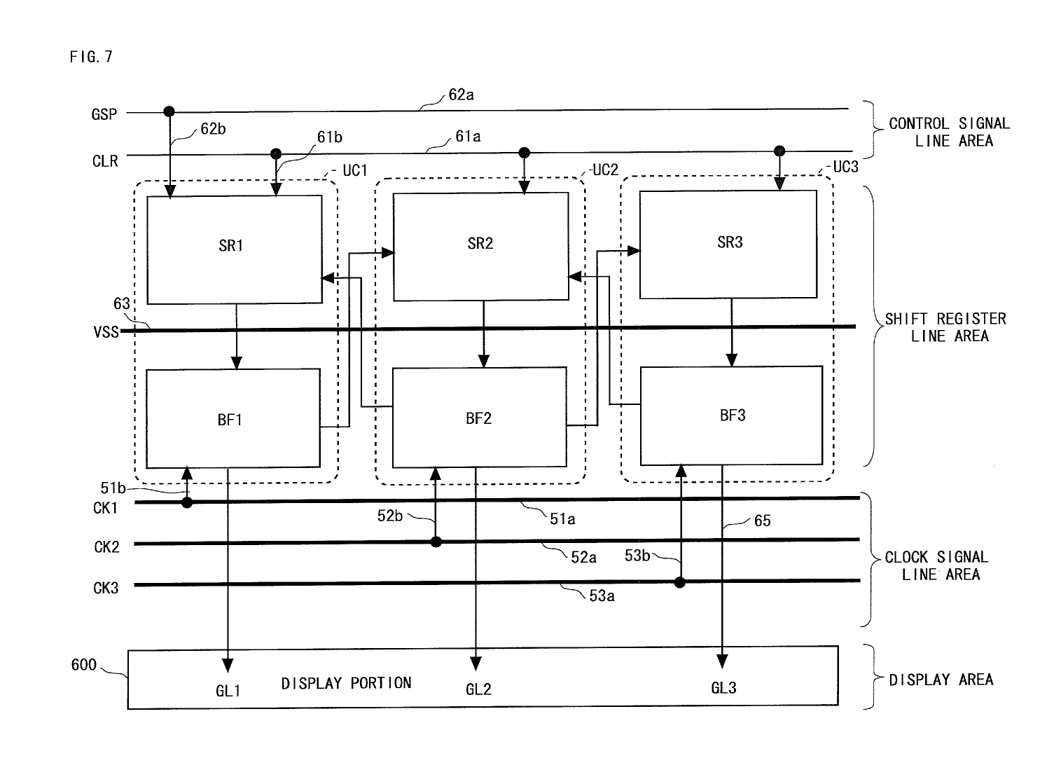

FIG. 7 is a diagram illustrating the wiring near the gate driver 400 in the present embodiment. In FIG. 7, among the n unit circuits UC1 to UCn, the first three unit circuits UC1 to UC3 and the wiring pattern in the proximity are shown. Each unit circuit UC consists of a bistable circuit SR and a buffer circuit BF. The buffer circuits BF are arranged in a line parallel to the display portion 600. The bistable circuits SR are disposed outside (in FIG. 7, above) the buffer circuits BF and arranged in a line parallel to the buffer circuits BF so as to be in one-to-one correspondence with the buffer circuits BF. Three gate clock signal bus lines 51a to 53a for transmitting the first gate clock signal CK1, the second gate clock signal CK2, and the third gate clock signal CK3, respectively, are formed parallel to the buffer circuits BF1 to BF3 in the area between the display portion 600 and the buffer circuits BF.

Further, in the area between the bistable circuits SR and the edge of the liquid crystal panel, a gate start pulse signal bus line 62a for transmitting the gate start pulse signal GSP and a clear signal bus line 61a for transmitting the clear signal CLR are formed parallel to the bistable circuits SR. Note that the gate start pulse signal bus line 62a and the clear signal bus line 61a for transmitting the clear signal CLR will be collectively referred to as the “control signal bus lines”.

Still further, in a shift register area in which the buffer circuits BF and the bistable circuits SR are disposed, a VSS bus line 63 for transmitting the low-level power source potential VSS to each of the unit circuits UC1 to UCn is formed. The buffer circuits BF output their respective gate clock signals CK1 to CK3 as output signals OUT, which are applied to the gate bus lines GL1 to GLn formed in the display portion 600 as scanning signals. As a result, the gate bus lines are selected sequentially.

The control signal bus lines, the bistable circuits SR, the buffer circuits BF, the VSS bus line 63, and the gate clock signal bus lines 51a to 53a are formed monolithically on the array substrate. In the following descriptions, the area in which the control signal bus lines are formed will be referred to as the “control signal line area”, and the area in which the gate clock signal bus lines 51a to 53a are formed will be referred to as the “clock signal line area”. Note that the bistable circuits and the buffer circuits adjacent thereto are connected by lines different from the aforementioned lines, and such lines will be described later.

The gate driver 400, pixel circuits, and other components, which are formed on the array substrate, are structured in layers. Such a layered structure includes two metallic films (i.e., metallic layers). One of the metallic films is used for forming the source electrodes (and the drain electrodes) of the thin-film transistors provided in the gate driver 400 and the pixel circuits and will be referred to as the “source metal”. The other metallic film is used for forming the gate electrodes of the thin-film transistors and will be referred to as the “gate metal”. The source metal overlies the gate metal. The source metal and the gate metal are used not only for the electrodes of the thin-film transistors but also for the wiring pattern formed in the gate driver 400 or the pixel circuits. Note that the wiring pattern formed with the source metal and the wiring pattern formed with the gate metal are electrically separated by an insulating film. Note that in the present embodiment, the source metal will also be referred to as the “first metallic film”, and the gate metal will also be referred to as the “second metallic film”.

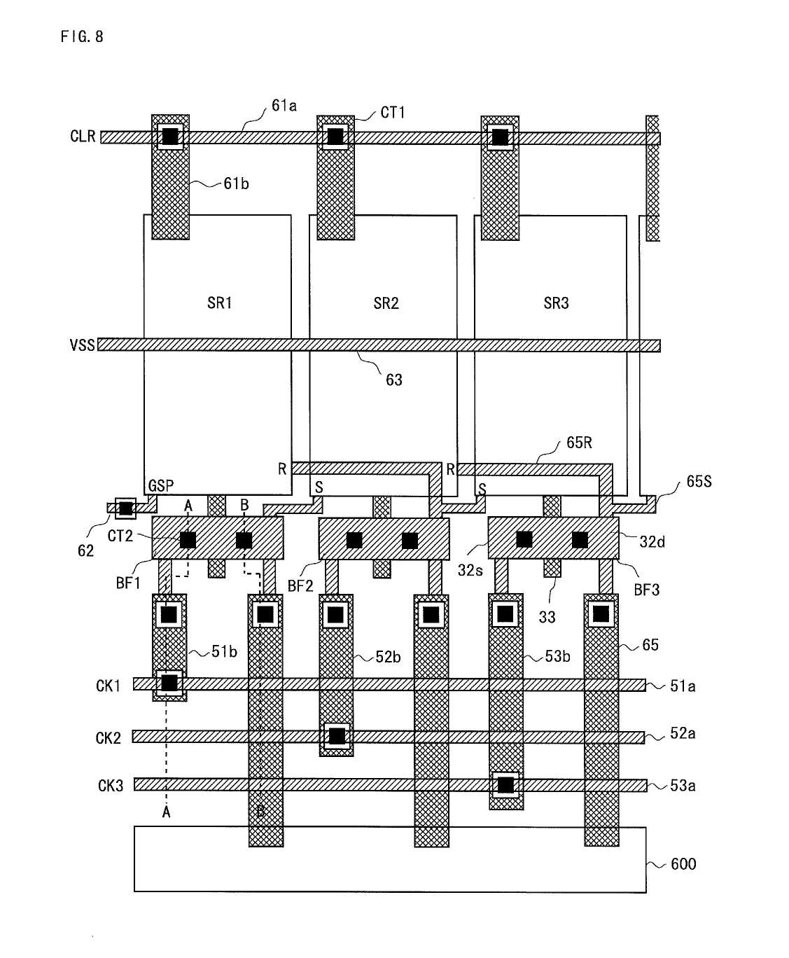

FIG. 8 is a diagram illustrating the layout of a wiring pattern near the gate driver in the present embodiment. In FIG. 8, among the n unit circuits UC1 to UCn, the first three unit circuits UC1 to UC3 and the wiring pattern in the proximity are shown. The clear signal bus line 61a for transmitting the clear signal CLR is formed in the control signal line area between the bistable circuits SR and the edge of the liquid crystal panel, as shown in FIG. 8. The gate start pulse signal line 62 for transmitting the gate start pulse signal GSP is connected to the bistable circuit SR1 in the first-stage unit circuit UC1. The clear signal bus line 61a is connected to clear signal branch lines 61b through contacts CT1, and the clear signal branch lines 61b are connected to their respective bistable circuits SR1 to SR3. Accordingly, the clear signal CLR is provided from the clear signal bus line 61a to each of the bistable circuits SR1 to SR3. Note that the gate start pulse signal line 62 and the clear signal bus line 61a are formed with the source metal, and the clear signal branch lines 61b are formed with the gate metal.

The buffer circuits BF1 to BF3 are single thin-film transistors whose gate electrodes 33 are connected to the output terminals of the bistable circuits SR. Each source electrode 32s is connected to one of the three gate clock signal bus lines 51a to 51c via their respective gate clock signal branch lines 51b to 53b. Each drain electrode 32d is connected to a gate bus line formed on the display portion 600 via a gate bus line connecting conductor 65. The gate clock signal bus lines 51a to 51c transmit the first gate clock signal CK1, the second gate clock signal CK2, and the third gate clock signal CK3, respectively. Accordingly, the source electrode 32s of the buffer circuit BF1 is connected to the gate clock signal bus line 51a via the gate clock signal branch line 51b, the source electrode 32s of the buffer circuit BF2 is connected to the gate clock signal bus line 52a via the gate clock signal branch line 52b, and the source electrode 32s of the buffer circuit BF3 is connected to the gate clock signal bus line 53a via the gate clock signal branch line 53b. Similar arrangements to the above arrangements for the first- to third-stage buffer circuits BF1 to BF3 are repeated every three stages. The bistable circuits SR1 to SR3 provide the potentials of their nodes NA as shown in FIG. 5 to the gate electrodes 33 of the buffer circuits as buffer control signals BC.

Furthermore, the drain electrode 32d of each thin-film transistor is connected to a reset terminal of the bistable circuit in the previous stage via a reset signal line 65R and also to a set terminal of the bistable circuit in the next stage via a set signal line 65S. Accordingly, the output signals OUT from the buffer circuits BF1 to BF3 are supplied to their corresponding gate bus lines in the display portion 600 as scanning signals, as well as to the bistable circuits in their respective previous stages as reset signals R and to the bistable circuits in their respective next stages as set signals S. For example, the output signal OUT from the drain electrode 32d of the thin-film transistor that serves as the second-stage buffer circuit BF2 is provided to the gate bus line GL2 as the scanning signal, as well as to the first-stage bistable circuit SR1 as the reset signal R and to the third-stage bistable circuit SR3 as the set signal S.

The source electrodes 32s and the drain electrodes 32d of the thin-film transistors and the gate clock signal bus lines 51a to 53a are formed with the source metal. The gate electrodes 33 of the thin-film transistors, the gate clock signal branch lines 51b to 53b, and the gate bus line connecting conductors 65 are formed with the gate metal. The VSS bus line 63, which connects the bistable circuits, is formed with the source metal. The source electrode 32s, the drain electrode 32d, and the gate electrode 33 will also be referred to as the “input electrode”, the “output electrode”, and the “control electrode”, respectively.

Note that the clear signal bus line 61a and the clear signal branch lines 61b, the gate clock signal bus lines 51a to 53a and the gate clock signal branch lines 51b to 53b, the gate clock signal branch lines 51b to 53b and the source electrodes 32s, and the gate bus line connecting conductors 65 and the drain electrodes 32d are connected via their respective contacts CT1, respectively. Moreover, the source electrodes 32s and source areas (not shown) of the semiconductor layers, and the drain electrodes 32d and drain areas (not shown) of the semiconductor layers are connected via their respective contacts CT2, respectively. Note that to avoid complexity, the gate clock signal branch lines for providing the three gate clock signals, i.e., the first, second, and third gate clock signals CK1 to CK3, to the bistable circuits SR1 to SR3 via the gate clock signal branch lines 51b to 53b are omitted in FIG. 8. Furthermore, in the present embodiment, the thin-film transistors used as the buffer circuits have been described assuming that they are n-channel transistors, but they may be p-channel transistors.

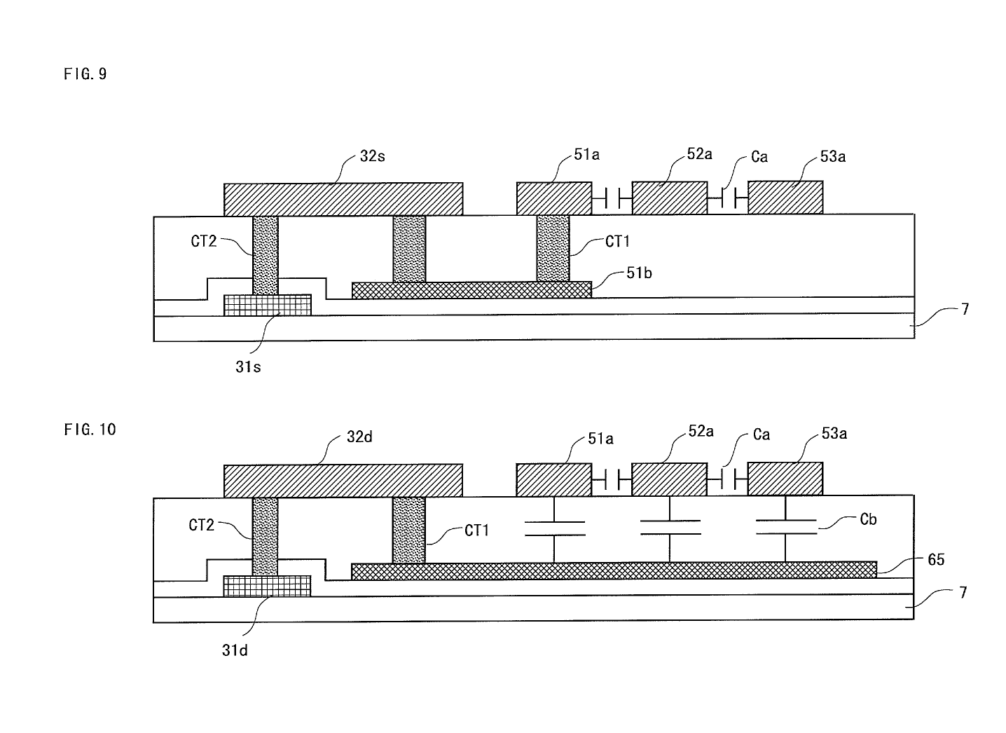

FIG. 9 is a cross-sectional view taken along line A-A shown in FIG. 8, and FIG. 10 is a cross-sectional view taken along line B-B shown in FIG. 8. On the left side of FIG. 9, the source electrode 32s of the buffer circuit and the source area 31s of the semiconductor layer, which is made with a semiconductor such as silicon, are formed. The three gate clock signal bus lines 51a to 53a, which are made with the source metal, and the gate clock signal branch line 51b, which is made with the gate metal, are formed to the right and separated by an interlayer insulating film. The gate clock signal branch line 51b extends only below the gate clock signal bus line 51a, which is the closest to the source electrode 32s among the three gate clock signal bus lines 51a to 53a.

Furthermore, on the left side of FIG. 10, the drain electrode 32d of the buffer circuit and the drain area 31d of the semiconductor layer, which is made with a semiconductor such as silicon, are formed. The three gate clock signal bus lines 51a to 53a, which are made with the source metal, and the gate bus line connecting conductor 65, which is made with the gate metal, are formed to the right and separated by the interlayer insulating film. The gate bus line connecting conductor 65, unlike the gate clock signal branch line 51b shown in FIG. 9, extends even below the gate clock signal bus line 53a, which is the furthest from the drain electrode 32d.

Note that the source electrodes 32s and the source areas 31s, and the drain electrodes 32d and the drain areas 31d are connected by their respective contacts CT2, respectively, and the gate clock signal bus line 51a and the gate clock signal branch line 51b, and the drain electrodes 32d and the gate bus line connecting conductors 65 are also connected by their respective contacts CT2, respectively.

The loads on the gate clock signal bus lines 51a to 53a shown in FIG. 9 include fringe capacitance Ca between the three gate clock signal bus lines 51a to 53a and the wiring resistance of the gate clock signal branch line 51b, which extends from the gate clock signal bus line 51a, which is the closest gate clock signal bus line to the source electrode 32s, to the source electrode 32s. Moreover, the loads on the gate clock signal bus lines 51a to 53a shown in FIG. 10 include interlayer capacitance Cb between each of the three gate clock signal bus lines 51a to 53a and the gate bus line connecting conductor 65, the fringe capacitance Ca between the three gate clock signal bus lines 51a to 53a, and the wiring resistance of the gate bus line connecting conductor 65.

In the present embodiment, the gate clock signal bus lines 51a to 53a are disposed near the thin-film transistor, which is the buffer circuit, and therefore, the distance from each of the gate clock signal bus lines 51a to 53a to the thin-film transistor is short, whereby the wiring resistance between the gate clock signal bus lines 51a to 53a and the thin-film transistor can be reduced. Moreover, the gate clock signal bus lines 51a to 53a and the control signal bus lines, such as the clear signal branch line 61b, are formed in separate areas, so that the control signal branch lines cross neither the gate clock signal bus lines 51a to 53a nor the bistable circuits, for example. Thus, the loads on the gate clock signal bus lines 51a to 53a can be reduced.

### 1.6 Effects

In the present embodiment, in the shift register 410, which writes the voltages of the gate clock signals CK1 to CK3 to the gate bus lines GL via the buffer circuits BF, the gate clock signal bus lines 51a to 53a, unlike the control signal bus lines and so on, are disposed in the clock signal line area between the display portion 600 and the buffer circuits BF. This results in no area in which the control signal bus lines cross the gate clock signal bus lines 51a to 53a and the wiring lines in the bistable circuits SR. Therefore, the interlayer capacitance Cb due to the crossings of the lines and the fringe capacitance Ca between the lines can be eliminated, leaving only the interlayer capacitance Cb between the gate clock signal bus lines 51a to 53a and the gate clock signal branch lines 51b to 53b and the fringe capacitance Ca between adjacent pairs of the gate clock signal bus lines 51a to 53a. In addition, the gate clock signal bus lines 51a to 53a are disposed near the buffer circuit BF, so that the distance from each of the gate clock signal bus lines 51a to 53a to the buffer circuit BF is short, resulting in reduced wiring resistance. Thus, the loads on the gate clock signal bus lines 51a to 53a can be reduced, whereby consumption of the current flowing through the gate clock signal bus lines 51a to 53a can be reduced.

Further, the gate clock signal bus lines 51a to 53a are formed with the first metallic film, and the gate clock signal branch lines 51b to 53b are formed with the second metallic film. Accordingly, it is possible to readily apply such a layout as to reduce the interlayer capacitance Cb due to the gate clock signal bus lines 51a to 53a crossing the gate clock signal branch lines 51b to 53b.

Still further, the set signal line 65S and the reset signal line 65R, which respectively provide the set signal S and the reset signal R to the bistable circuit SR, are formed with the same metallic film as the output line 68 of the buffer circuit BF. Accordingly, it is possible to readily apply a layout such that the output signal OUT of each unit circuit US is provided to the unit circuit UC in the next stage as the set signal S or to the unit circuit UC in the previous stage as the reset signal R.

Yet further, each buffer circuit BF is formed by a single thin-film transistor, and the source electrode 32s and the drain electrode 32d of the thin-film transistor are formed with the same metallic film as the gate clock signal bus lines 51a to 53a. Accordingly, it is possible to readily apply a layout such that the source electrodes 32s and the drain electrodes 32d are connected to the gate clock signal bus lines 51a to 53a or the gate bus lines.

### 2. Second Embodiment

Next, a second embodiment of the present invention will be described. The overall configuration of a liquid crystal display device according to the present embodiment is the same as the configuration in the first embodiment as shown in FIGS. 1 and 2, and therefore, any description and diagram thereof will be omitted.

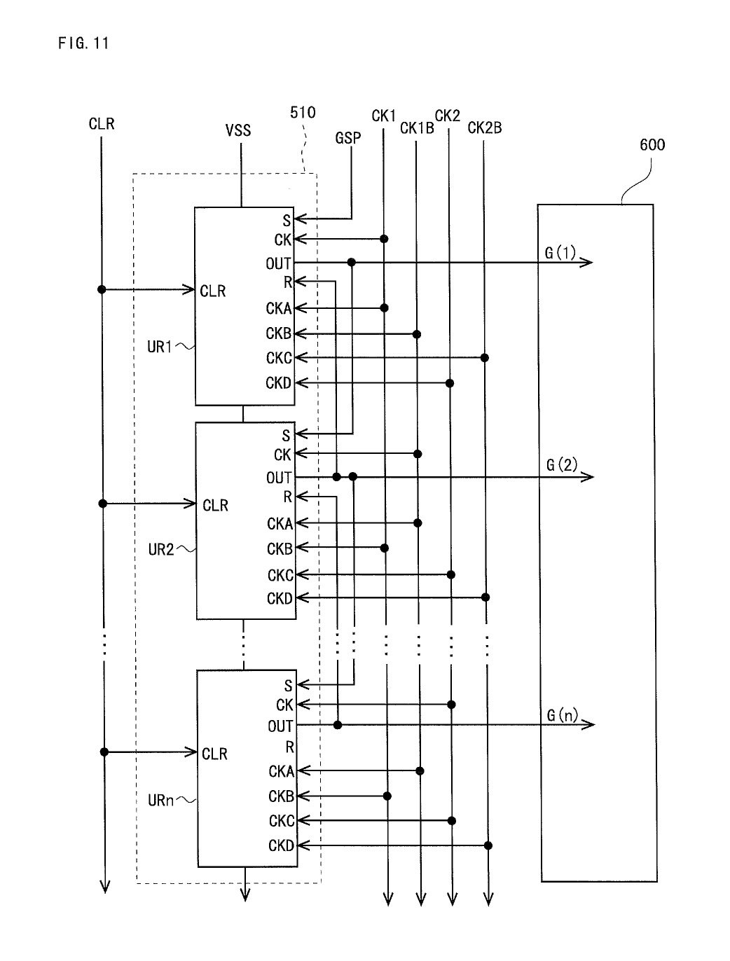

FIG. 11 is a block diagram illustrating the configuration of a shift register 510 in a gate driver. The shift register 510 shown in FIG. 11 also consists of n unit circuits UR1 to URn. Each of the unit circuits UR1 to URn are provided with control signals, such as a gate start pulse signal GSP and a clear signal CLR, as well as a four-phase gate clock signal. The four-phase gate clock signal consists of a first gate clock signal CK1, a second gate clock signal CK1B, a third gate clock signal CK2, and a fourth gate clock signal CK2B. Each unit circuit is provided with input terminals for receiving a clock signal CKA (referred to below as a “first clock”), a clock signal CKB (referred to below as a “second clock”), a clock signal CKC (referred to below as a “third clock”), and a clock signal CKD (referred to below as a “fourth clock”), an input terminal at which to receive the set signal S, an input terminal for receiving a reset signal R, an input terminal for receiving the clear signal CLR, and an output terminal for outputting an output signal OUT. The gate clock signals CK1 to CK2B alternate between a high-level power source potential VDD and a low-level power source potential VSS every predetermined period of time.

The following signals are provided to the input terminals of the stages (i.e., the unit circuits) in the shift register 510. A first gate clock signal CK1, a second gate clock signal CK1B, a fourth gate clock signal CK2B, and a third gate clock signal CK2 are provided to the first-stage unit circuit UR1 as the first clock CKA, the second clock CKB, the third clock CKC, and the fourth clock CKD, respectively. The second gate clock signal CK1B, the first gate clock signal CK1, the third gate clock signal CK2, and the fourth gate clock signal CK2B are provided to the second-stage unit circuit UR2 as the first clock CKA, the second clock CKB, the third clock CKC, and the fourth clock CKD, respectively. For the third-stage unit circuit UR3 onward, similar arrangements to the above arrangements for the first and second stages are repeated every two stages.

Furthermore, each stage (i.e., each unit circuit) is provided with a set signal S, which is an output signal OUT from the previous stage, as well as a reset signal R, which is an output signal OUT from the next stage. More specifically, the output signal OUT from each unit circuit is provided not only to the gate bus line as a scanning signal but also to the next stage as a set signal S and to the previous stage as a reset signal R. Note that the first-stage unit circuit UR1 is provided with a gate start pulse signal GSP serving as a set signal S. Moreover, the low-level power source potential VSS and the clear signal CLR are provided commonly to all unit circuits.

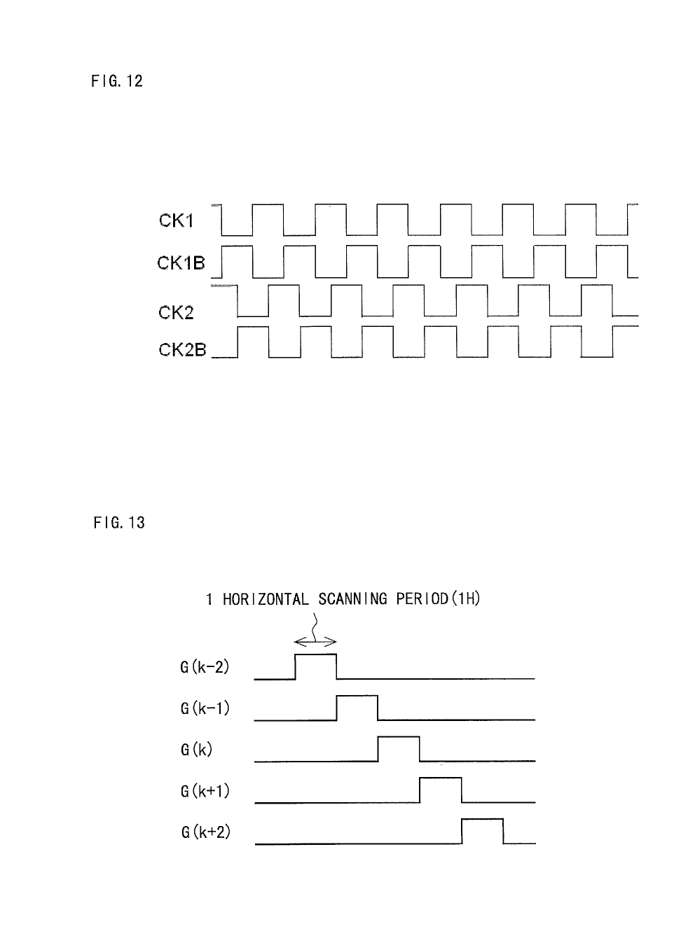

FIGS. 12 and 13 provide signal waveform charts describing the operation of the gate driver. As shown in FIG. 12, the first gate clock signal CK1 and the second gate clock signal CK1B are out of phase from each other by 180 degrees (i.e., by a time period equivalent to one horizontal scanning period), and the third gate clock signal CK2 and the fourth gate clock signal CK2B are out of phase from each other by 180 degrees. Moreover, the third gate clock signal CK2 is 90 degrees behind in phase relative to the first gate clock signal CK1. All of the gate clock signals CK1, CKB1, CK2, and CK2B are set to high level (“H” level) every horizontal scanning period.

When the gate start pulse signal GSP is provided to the first-stage unit circuit UR1 of the shift register 410 as the set signal S, pulses included in the gate start pulse signal GSP are transferred sequentially from the first-stage unit circuit UR1 through the n'th-stage unit circuit URn in accordance with the gate clock signals CK1, CKB1, CK2, and CK2B. In accordance with the pulse transfer, the output signals OUT from the stages of the shift register 510 are sequentially set to high level. In this manner, the output signal OUT, which is maintained at high level for one horizontal scanning period, is provided by each unit circuit, and this status signal is provided to the gate bus line as a scanning signal.

### 2.1 Configuration and Operation of the Unit Circuit

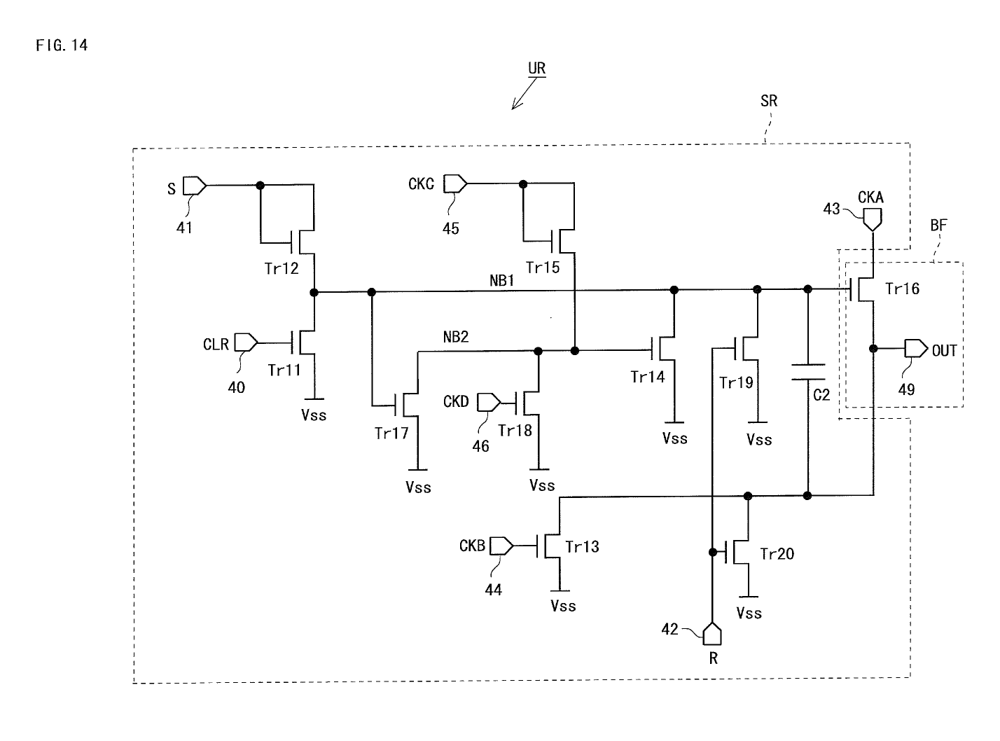

FIG. 14 is a circuit diagram illustrating the configuration of the unit circuit UR included in the shift register 510 in the present embodiment. The bistable circuit SR includes ten thin-film transistors Tr11 to Tr20 and a capacitor C2, as shown in FIG. 14. Moreover, the bistable circuit SR includes an input terminal 43 at which to receive the first clock CKA, an input terminal 44 at which to receive the second clock CKB, an input terminal 45 at which to receive the third clock CKC, an input terminal 46 at which to receive the fourth clock CKD, an input terminal 41 at which to receive the set signal S, an input terminal 42 at which to receive the reset signal R, an input terminal 40 at which to receive the clear signal CLR, and an output terminal 49 from which to output the output signal OUT. Note that as in the first embodiment, the aforementioned thin-film transistors Tr11 to Tr20 are formed on the array substrate and have semiconductor layers made with amorphous silicon, polycrystalline silicon, microcrystalline silicon, or an oxide semiconductor such as indium gallium zinc oxide. Moreover, as in the case of the unit circuit UC shown in FIG. 5, the thin-film transistor Tr16 and the output terminal 49 constitute a buffer circuit BF, and the thin-film transistors Tr11 to Tr15 and Tr17 to Tr20, the capacitor C2, and the input terminals 40 to 46 constitute a bistable circuit SR.

Next, the connection relationship between the components in the unit circuit UR will be described. A source terminal of the thin-film transistor Tr12, a drain terminal of the thin-film transistor Tr11, a gate terminal of the thin-film transistor Tr17, a drain terminal of the thin-film transistor Tr14, a drain terminal of the thin-film transistor Tr19, a gate terminal of the thin-film transistor Tr16, and one terminal of the capacitor C2 are connected to one another. Note that the line that connects them will be referred to as the “first node NB1”.

A drain terminal of the thin-film transistor Tr17, a drain terminal of the thin-film transistor Tr18, a source terminal of the thin-film transistor Tr15, and a gate terminal of the thin-film transistor Tr14 are connected to one another. Note that the line that connects them will be referred to as the “second node NB2”.

Next, the function of each component in the unit circuit will be described. The thin-film transistor Tr11 sets the potential of the first node NB1 to low level when the clear signal CLR is at high level. The thin-film transistor Tr12 sets the potential of the first node NB1 to high level when the set signal S is at high level. The thin-film transistor Tr16 provides the potential of the first clock CKA to the output terminal 49 when the potential of the first node NB1 is at high level. The thin-film transistor Tr15 sets the potential of the second node NB2 to high level when the third clock CKC is at high level.

The thin-film transistor Tr17 sets the potential of the second node NB2 to low level when the potential of the first node NB1 is at high level. While the gate bus line connected to the output terminal 49 of the unit circuit UR is being selected, if the second node NB2 is set to high level so that the thin-film transistor Tr14 is brought into on-state, the potential of the first node NB1 decreases, so that the thin-film transistor Tr16 is brought into off-state. The thin-film transistor Tr17 is provided in order to prevent such a phenomenon.

The thin-film transistor Tr18 sets the potential of the second node NB2 to low level when the fourth clock CKD is at high level. If the thin-film transistor Tr18 is not provided, the potential of the second node NB2 is always at high level except during selection periods, so that a bias voltage is kept applied to the thin-film transistor Tr14. In such a case, the threshold voltage of the thin-film transistor Tr14 rises, so that the thin-film transistor Tr14 does not function sufficiently as a switch. The thin-film transistor Tr18 is provided in order to prevent such a phenomenon.

The thin-film transistor Tr14 sets the potential of the first node NB1 to low level when the potential of the second node NB2 is at high level. The thin-film transistor Tr19 sets the potential of the first node NB1 to low level when the reset signal R is at high level. The thin-film transistor Tr20 sets the potential of the output terminal 49 to low level when the reset signal R is at high level. The thin-film transistor Tr13 sets the potential of the output terminal 49 to low level when the second clock CKB is at high level. The capacitor C2 functions as compensation capacitance for maintaining the potential of the first node NB1 at high level while the gate bus line connected to the output terminal 49 of the unit circuit is being selected.

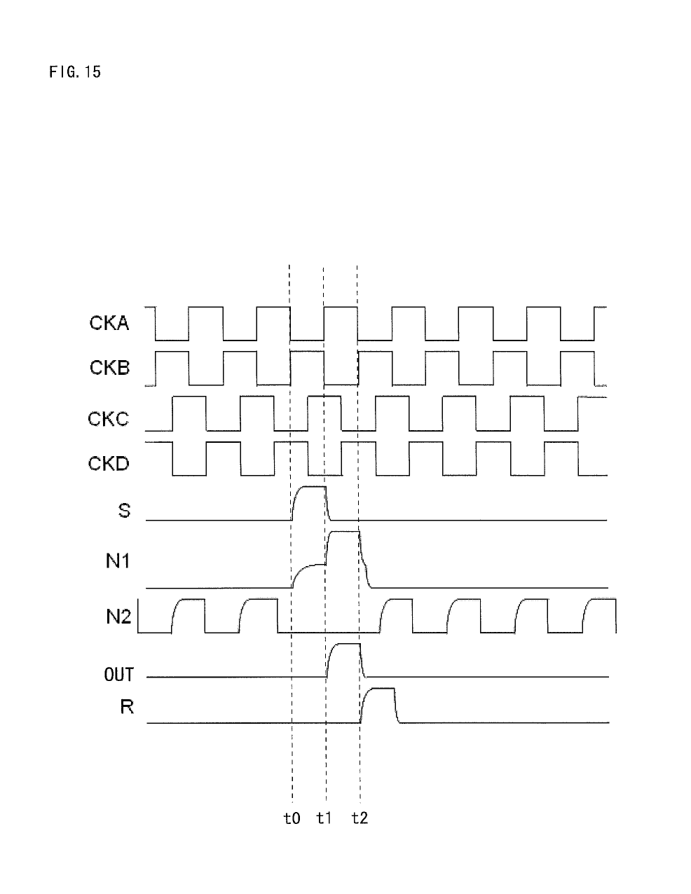

Next, the operation of the unit circuit will be described. FIG. 15 provides signal waveform charts describing the operation of the shift register 510. At time to, as shown in FIG. 15, a pulse of the set signal S, along with the clock signals CKA to CKD, are provided to the unit circuit. The thin-film transistor Tr12 is diode-connected, and therefore, the first node NB1 is precharged by the pulse of the set signal S. During this period, the thin-film transistor Tr17 is in on-state, so that the potential of the second node NB2 is at low level. Moreover, during this period, the reset signal R is at low level. Accordingly, the thin-film transistor Tr14 and the thin-film transistor Tr19 are in off-state, so that the potential of the first node NB1, which has been raised by precharge, does not fall during this period.

At time t1, the first clock CKA changes from low level to high level. Here, the first clock CKA is provided to the source terminal of the thin-film transistor Tr16, and also, there is parasitic capacitance (not shown) between the gate and the source of the thin-film transistor Tr16. Accordingly, as the source potential of the thin-film transistor Tr16 rises, the potential of the first node NB1 rises as well by virtue of bootstrap effect. As a result, the thin-film transistor Tr16 is brought into on-state. The first clock CKA is maintained at high level, and therefore, the output signal OUT is set to high level. Consequently, the gate bus line that is connected to the unit circuit outputting the output signal OUT at high level is brought into a selected state, a video signal is written to pixel capacitance Cp in the pixel forming portions in the row that corresponds to the gate bus line. Note that, during this period also, the thin-film transistor Tr14 and the thin-film transistor Tr19 are in off-state, and therefore, the potential of the first node NB1 does not decrease.

At time t2, the first clock CKA changes from high level to low level. Moreover, the second clock CKB changes from low level to high level. In addition, the reset signal R changes from low level to high level. As a result, the thin-film transistors Tr13, Tr19, and Tr20 are brought into on-state. As a result of the thin-film transistors Tr13 and Tr20 being brought into on-state, the potential of the output signal OUT falls to low level. Moreover, the thin-film transistor Tr19 is brought into on-state, so that the potential of the first node NB1 falls to low level.

The operations as above will be repeated so that significant increases in potential due to bootstrap effect occur sequentially in the first nodes NB1(1) to NB1(n) of the first- to n'th-stage unit circuits UR1 to URn, and the output signals OUT(1) to OUT(n) respectively provided by the first- to n'th-stage unit circuits UR1 to URn are sequentially set at high level for a predetermined period of time.

In this manner, the output signal OUT, which is maintained at high level for one horizontal scanning period, is provided by each bistable circuit and supplied to the gate bus line as a scanning signal G.

### 2.2 Layout for the Gate Driver

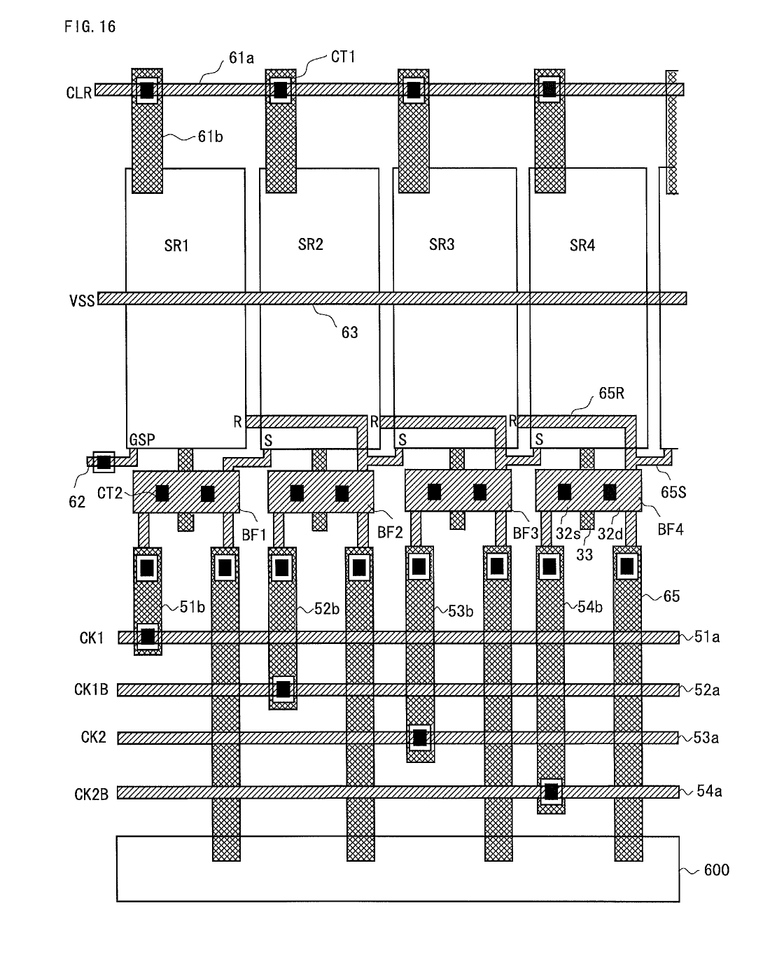

FIG. 16 is a diagram illustrating the layout of a wiring pattern near the gate driver in the present embodiment. In the present embodiment, the four gate clock signal bus lines 51a to 54a are disposed in the area between the display portion and the buffer circuits, as shown in FIG. 16. That is, when compared to the gate clock signal bus lines 51a to 53a shown in FIG. 8, there is one more gate clock signal bus line. The gate clock signals CK1, CK1B, CK2, and CK2B from the gate clock signal bus lines 51a to 54a are provided to the buffer circuits BF1 to BF4 via the gate clock signal branch lines 51b to 54b. In this manner, the layout near the buffer circuits differs from the layout shown in FIG. 8 in that similar arrangements to the arrangements for the first- to fourth-stage unit circuits UR1 to UR4 are repeated every four stages. The layout for the rest of the wiring pattern is the same as in the case shown in FIG. 8, and therefore, any description thereof will be omitted. Note that in FIG. 16 also, to avoid the figure becoming complex, the gate clock signal branch lines for providing the four gate clock signals CK1, CK1B, CK2, and CK2B to the bistable circuits SR1 to SR4 via the gate clock signal branch lines 51b to 54b are omitted.

### 2.3 Effects

In the present embodiment, there is one more gate clock signal bus line than in the first embodiment. However, as in the first embodiment, it is possible to eliminate the areas where the control signal branch lines cross the gate clock signal bus lines 51a to 54a and the wiring lines in the bistable circuits. Accordingly, it is possible to eliminate the interlayer capacitance Cb due to the crossings of the lines as well as the fringe capacitance Ca between the lines, leaving only the interlayer capacitance Cb between the gate clock signal bus lines 51a to 54a and the gate clock signal branch lines 51b to 54b and the fringe capacitance between adjacent pairs of the gate clock signal bus lines 51a to 54a. In addition, the gate clock signal bus lines 51a to 54a are disposed near the buffer circuit BF, so that the distance from each of the gate clock signal bus lines 51a to 54a to the buffer circuit BF is short, resulting in reduced wiring resistance. Thus, the loads on the gate clock signal bus lines 51a to 54a can be reduced, whereby consumption of the current flowing through the gate clock signal bus lines 51a to 54a can be reduced.

### 3. Third Embodiment

Next, a third embodiment of the present invention will be described. The configuration of the buffer circuit in the present embodiment is the same as those in the liquid crystal display devices shown in FIGS. 1 to 8, except that a CMOS (Complementary Metal Oxide Semiconductor) logic gate circuit in which a NAND circuit and an inverter circuit are connected in series is used in place of the single thin-film transistor used in the first embodiment. Therefore, any descriptions and diagrams of the configurations and the operations of the liquid crystal display device according to the present embodiment and its shift register and unit circuit will be omitted.

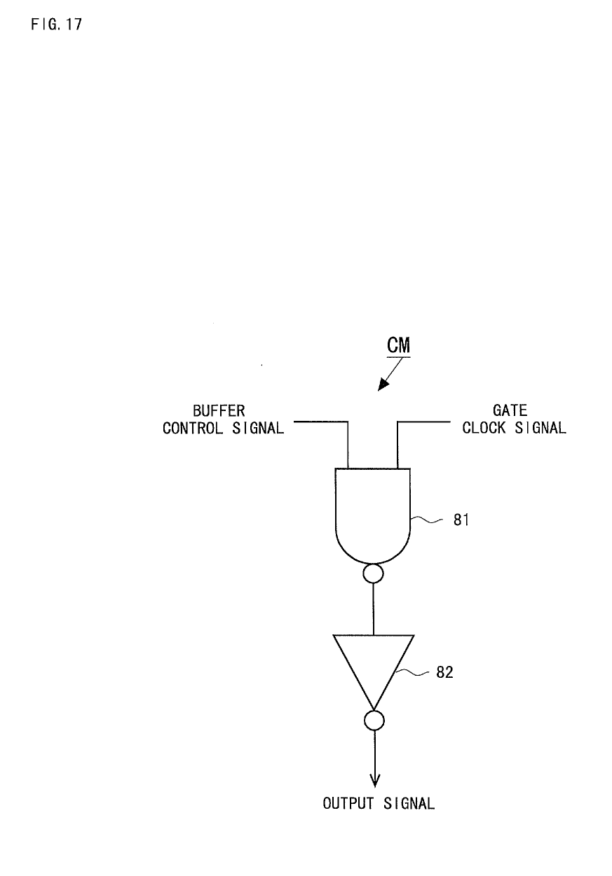

FIG. 17 is a diagram illustrating the configuration of a CMOS logic gate circuit CM included in the shift register in the present embodiment. The CMOS logic gate circuit CM is a circuit in which a NAND circuit 81 and an inverter circuit 82 are connected in series, as shown in FIG. 17. The NAND circuit 81 receives a buffer control signal outputted by the bistable circuit at one input terminal and one of the gate clock signals CK1 to CK3 from the three gate clock signal bus lines 51a to 54a at the other input terminal.

The CMOS logic gate circuit CM outputs a high-level signal when both the buffer control signal and the gate clock signal are at high level, and also outputs a low-level signal in other cases. More specifically, the CMOS logic gate circuit CM provides output signals in the same cycles as gate clock signals are outputted. However, unlike the single thin-film transistor in the first embodiment, the CMOS logic gate circuit CM amplifies the gate clock signals CK1 to CK3 before outputting them, and therefore, the gate clock signals CK1 to CK3 are outputted at a higher level than the original level.

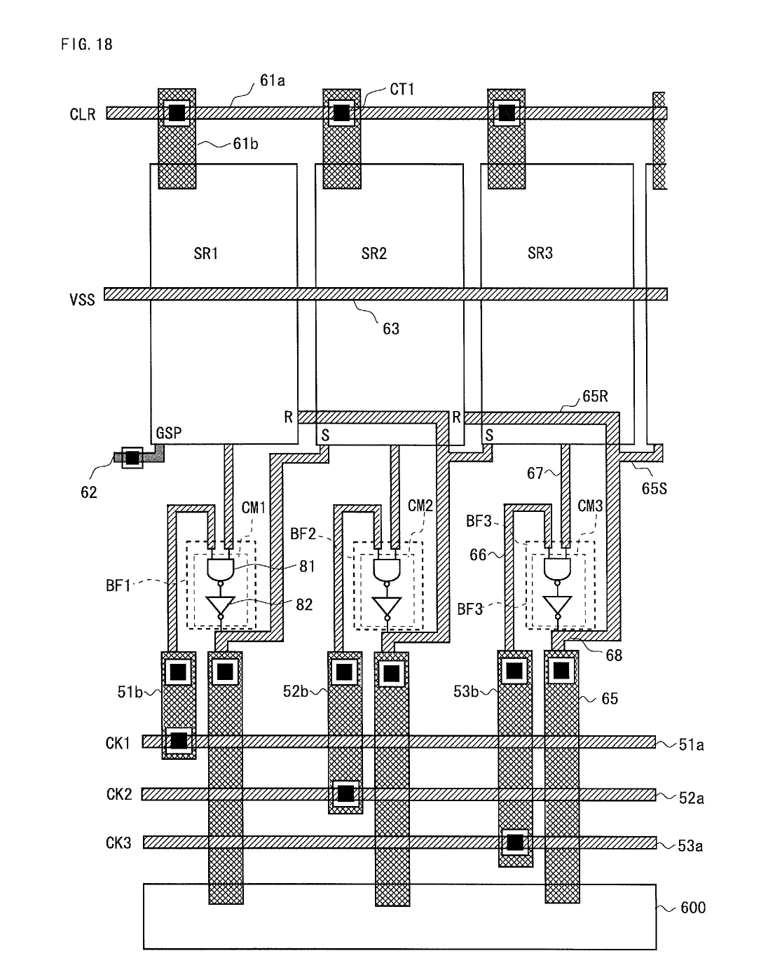

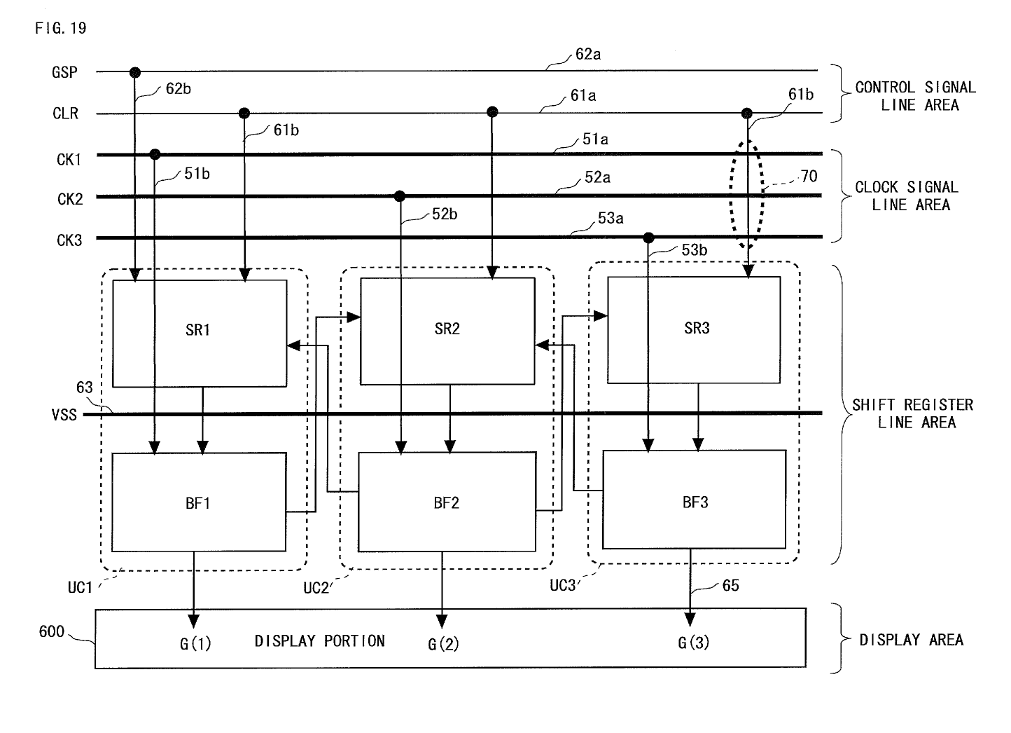

FIG. 18 is a diagram illustrating the layout of a wiring pattern near the gate driver 400 in the present embodiment. The layout shown in FIG. 18 differs from the layout shown in FIG. 8 in that the CMOS logic gate circuit CM in which the NAND circuit 81 and the inverter circuit 82 are connected in series is used as the buffer circuit, and the layout for the rest of the wiring pattern is the same as in the case shown in FIG. 8. The NAND circuit 81 is provided at one input terminal with one of the gate clock signals CK1 to CK3 via a first input line 66 and at the other input terminal with a buffer control signal from the bistable circuit SR via a second input line 67. Moreover, an output terminal thereof is connected to an output line 68, which is connected to the gate bus line connecting conductor 65 as well as to the reset signal line 65R and the set signal line 65S. As described above, the layout near the buffer circuit differs from that shown in FIG. 8, but the layout for the rest of the wiring pattern is the same as in FIG. 8, and therefore, any description thereof will be omitted.

The buffer circuit described in the present embodiment is the CMOS logic gate circuit CM in which the NAND circuit 81 and the inverter circuit 82 are connected in series. However, this is not limiting, and any CMOS logic gate circuits may be used so long as the gate clock signals CK1 to CK3 are outputted in accordance with buffer control signals outputted by the bistable circuits.

### 3.1 Effects

The present embodiment renders it possible to achieve the same effects as those described in the first embodiment. Moreover, even when the levels of the gate clock signals CK1 to CK3 are low, the gate clock signals CK1 to CK3 can be amplified by the buffer circuits, and therefore, it is possible to output scanning signals at sufficient levels to the gate bus lines. Accordingly, it is possible to reduce current consumption by the gate clock signal bus lines 51a to 53a more than in the first embodiment.

### 4. Others

The above embodiments have been described taking as an example the liquid crystal display device. However, this is not limiting, and the present invention can also be applied to other display devices such as organic EL (Electro Luminescent) display devices.

### INDUSTRIAL APPLICABILITY

The invention is applicable to display devices capable of suppressing current consumption, particularly to a liquid crystal display device capable of suppressing consumption of the current flowing through gate clock signal bus lines.

### DESCRIPTION OF THE REFERENCE CHARACTERS

7 array substrate
51a to 53a gate clock signal bus line
51b to 53b gate clock signal branch line
61a clear signal bus line
61b clear signal branch line
65 gate bus line connecting conductor
65S set signal input line
65R reset signal input line
400 gate driver
410, 510 shift register
600 display portion
BF1 to BF3 buffer circuit
CM CMOS logic gate circuit
GL gate bus line
SR bistable circuit
UC, UR unit circuit

1. A display device, comprising:
a substrate;
pixel circuits formed in a display area on the substrate in which to display an image;
a plurality of scanning signal lines formed in the display area, each constituting a part of the pixel circuit;
a shift register formed on the substrate and having a plurality of bistable circuits and a plurality of buffer circuits, the bistable circuits having first and second states and being provided in one-to-one correspondence with the scanning signal lines, the buffer circuits being connected in series to the respective bistable circuits so as to, when the bistable circuits are sequentially brought into the first state, output clock signals provided by a plurality of clock signal bus lines for transmitting the respective clock signals, to the scanning signal lines being driven sequentially by the bistable circuits being sequentially brought into the first state; and
control signal bus lines formed in an area opposite to the display area with respect to a shift register area in which the shift register is formed, the control signal bus lines transmitting control signals for controlling the operation of the bistable circuits and being connected to the bistable circuits by control signal branch lines, wherein,
the buffer circuits are formed in a line within the shift register area so as to be opposed to the display area, and
the clock signal bus lines are formed in an area between the shift register area and the display area so as to be adjacent to the buffer circuits.

2. The display device according to claim 1, wherein,
the substrate has a layered structure including a first metallic film and a second metallic film, the first metallic film bistable the second metallic film forming a wiring pattern including gate electrodes of the thin-film transistors, and
the clock signal bus lines and a plurality of clock signal branch lines are respectively formed with the first metallic film and the second metallic film.

3. The display device according to claim 2, wherein,
each of the bistable circuits includes a set signal input terminal for receiving a set signal and a reset signal input terminal for receiving a reset signal,
each of the buffer circuits has an output line connected by a set signal line to a set signal input terminal of the bistable circuit in the next stage and also connected by a reset signal line to a reset signal input terminal of the bistable circuit in the previous stage, and
the set signal line and the reset signal line are formed with the same metallic film as the output line.

4. The display device according to claim 2, wherein,
each of the buffer circuits includes a single thin-film transistor,
the thin-film transistor has an input electrode connected to one of the clock signal bus lines, an output electrode connected to one of the scanning signal lines, and a control electrode connected to an output terminal of one of the bistable circuits, and
the input electrode and the output electrode are formed with the same metallic film as the clock signal bus lines.

5. The display device according to claim 4, wherein each of the clock signal branch lines is formed extending to a position at which to be connected to the clock signal bus line that is connected to the input electrode.

6. The display device according to claim 4, wherein the thin-film transistor has a semiconductor layer made with InGaZnOx mainly composed of indium (In), gallium (Ga), zinc (Zn), and oxygen (O).

7. The display device according to claim 2, wherein the buffer circuits have first and second input terminals and output terminals and include CMOS logic gate circuits for outputting scanning signals to the scanning signal lines when the respective bistable circuits are in the first state.

8. The display device according to claim 2, wherein the control signal bus line is formed with the first metallic film and the control signal branch line is formed with the second metallic film.
